(19) United States
(12) Patent Application Publication
(10) Pub. No.: US 2009/0302451 A1
(43) Pub. Date: Dec. 10, 2009

(54) Semiconductor device having function circuits selectively connected to bonding wire

(75) Inventor: Yoshihisa Matsubara, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC Electronics Corporation, Kawasaki (JP)

(21) Appl. No.: 12/453,931

(22) Filed: May 27, 2009

(30) Foreign Application Priority Data
Jun. 10, 2008 (JP) 2008-151435

(51) Int. Cl. H01L 23/48; H01L 23/488; H01L 23/02

(52) U.S. Cl. 257/691; 257/737; 257/690; 257/E23.01; 257/E23.023; 257/E23.18

(57) ABSTRACT

A semiconductor device includes a semiconductor chip, a wiring substrate, and wires. The semiconductor chip includes a first circuit, a second circuit having a function differing from that of the first circuit, a plurality of first pads disposed in a row along one side of the semiconductor chip and connected to the first circuit, and a plurality of second pads disposed between both of the first and second circuits and the first pads, and connected to the second circuit. The wiring substrate includes a plurality of terminals and the plurality of wires is connected between a plurality of terminals provided outside of the semiconductor chip, and ones of the first pads and the second pads. The wires are free from the other of the first pads and the second pads, and the plurality of the wires being not intersected to each other.

### INCORPORATION BY REFERENCE

This application is based upon and claims the benefit of priority from Japanese Patent Application No. 2008-151435 which was filed on Jun. 10, 2008, the disclosure of which is incorporated herein in its entirety by reference.

### BACKGROUND OF THE INVENTION

1. Field of the Invention

The present invention relates to a semiconductor device, and in particular, to a semiconductor device having plural pad lines and plural function circuits and bonding wires connected to the pad lines.

2. Description of Related Art

As one of methods for mounting a semiconductor chip on a wiring substrate, there is a method for connecting the wiring substrate to the semiconductor chip by bonding wires. This method is, for example, provided to connect an inner lead of a lead frame, as the wiring substrate, with a pad of the semiconductor chip by a bonding wire.

Meanwhile, Patent Document 1 discloses a technology for forming plural circuits differing in function from each other on a semiconductor chip, and selecting a circuit to be connected with a wiring substrate from among those circuits. In order to select the circuit to be connected with the wiring substrate, a bonding wire is used to connect a pad for the selected circuit with a wiring substrate.

Patent Document 2 discloses a microcomputer chip including plural first electrode pads disposed in the peripheral edge of the chip, and plural second electrode pads disposed on the inner side of the plural first electrode pads. The second electrode pads are only for use at the time of emulation, and are connected to an emulation circuit.

[Patent Document 1] Japanese Patent Application Laid Open No. Hei 05 (1993)-283468
[Patent Document 2] Japanese Patent Application Laid Open No. 2006-134107

### SUMMARY

For switching the function of a semiconductor chip by selecting a pad to be connected to a bonding wire, it is necessary to form a pad on a function-by-function basis, so that there results an increase in the number of the pads. Consequently, if the pads are arranged in a row, then this will inevitably cause the semiconductor chip to become larger in size. From the viewpoint of controlling an increase in the size of the semiconductor chip, it is conceivable that the pads are arranged in plural rows. However, if the pads are arranged in the plurality of rows, then this will cause bonding wires to come into close proximity to each other depending on how the pads are lined up, raising a possibility that a semiconductor device yield will be reduced.

Patent Document 1 discloses the selection of the pads. However, the patent document 1 does not discloses the pads arranged in plural rows or the arrangement of the pads every function circuits, or the connection method of the bonding wires between the pads arranged in plural rows and lead frames. Patent Document 2 discloses the semiconductor device having the pads arranged in rows. However, the inner pad row and the external pad row are used when emulation is conducted before resin seal. After the semiconductor device is sealed, the inner pad row is not used and the external pad row is only used. That is, as to the final product sealed by resin, the external pad is only connected to lead frames through bonding wires. Therefore, the patent document 2 does not teach or suggest selectively using different function circuits in the semiconductor device by changing the connection of the bonding wires, at the final product.

According to one exemplary aspect of the invention, a semiconductor device includes a semiconductor chip, a wiring substrate, and plural first wires for connecting the semiconductor chip with the wiring substrate; in which the semiconductor chip has plural first pads disposed along one side of the semiconductor chip, forming a first pad row, plural second pads disposed on a side of the plural first pads, adjacent to the center of the semiconductor chip, forming a second pad row, a first circuit connected to the plural first pads, and a second circuit connected to the plural second pads, having a function differing from that of the first circuit, in which the wiring substrate has plural first terminals, and in which the plural first wires each have one end connected to each of the plural first terminals, and the other end connected to each of either the plural first pads, or the plural second pads, the plural first wires not intersecting each other.

With the present invention, the plural second pads are disposed on a side of the plural first pads, adjacent to the center of the semiconductor chip. Accordingly, it is possible to miniaturize both the semiconductor chip and the semiconductor device, as compared with the case the plural second pads are disposed in the same row where the first pads are disposed. Further, since the plural first wires do not intersect each other, the interval between the first wires adjacent to each other can be secured. It is therefore possible to control deterioration in semiconductor device yield.

With the present invention, it is possible to miniaturize the semiconductor device while controlling deterioration in semiconductor device yield.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a plan view showing a configuration of a first exemplary embodiment of a semiconductor device according to the invention;

FIG. 2 is a plan view showing another configuration of the semiconductor device according to the first exemplary embodiment of the invention;

FIG. 3 is a view showing a relation between a wire critical interval and a semiconductor device yield;

FIG. 4 is a view showing a relation between a wire length and a semiconductor device yield;

FIG. 5 is a plan view showing a configuration of a second exemplary embodiment of a semiconductor device according to the invention;

FIG. 6 is a plan view showing another configuration of the semiconductor device according to the second exemplary embodiment of the invention;

FIG. 7 is a plan view showing a configuration of a third exemplary embodiment of a semiconductor device according to the invention;

FIG. 8 is a plan view showing another configuration of the semiconductor device according to the third exemplary embodiment of the invention;

FIG. 9 is a plan view showing a configuration of a fourth exemplary embodiment of a semiconductor device according to the invention;

FIG. 10 is a plan view showing another configuration of the semiconductor device according to the fourth exemplary embodiment of the invention;

FIG. 11 is a plan view showing a configuration of a fifth exemplary embodiment of a semiconductor device according to the invention;

FIG. 12 is a plan view showing another configuration of the semiconductor device according to the fifth exemplary embodiment of the invention;

FIG. 13 is a plan view showing a configuration of a sixth exemplary embodiment of a semiconductor device according to the invention;

FIG. 14 is a plan view showing another configuration of the semiconductor device according to the sixth exemplary embodiment of the invention;

FIG. 15 is a plan view showing a configuration of a seventh exemplary embodiment of a semiconductor device according to the invention;

FIG. 16 is a plan view showing another configuration of the semiconductor device according to the seventh exemplary embodiment of the invention;

FIG. 17 is a plan view showing a configuration of an eighth exemplary embodiment of a semiconductor device according to the invention; and

FIG. 18 is a plan view showing another configuration of the semiconductor device according to the eighth exemplary embodiment of the invention.

### DETAILED DESCRIPTION OF THE EXEMPLARY EMBODIMENTS

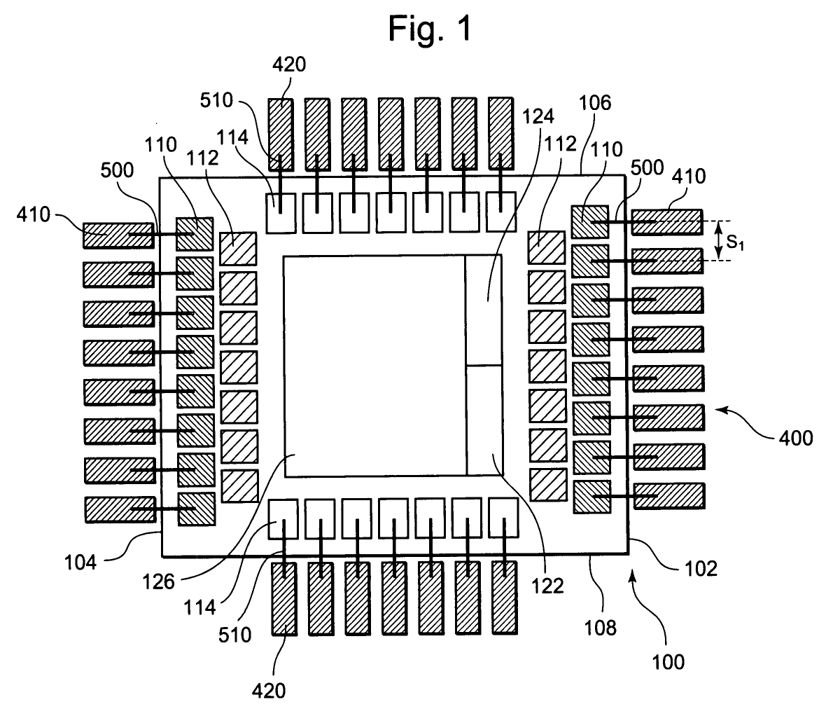

FIG. 1 is a plan view showing a configuration of a first exemplary embodiment of a semiconductor device according to the invention. The semiconductor device includes a semiconductor chip 100, a wiring substrate 400, and plural first wires 500 for connecting the semiconductor chip 100 with the wiring substrate 400.

The semiconductor chip 100 is provided with plural first pads 110, plural second pads 112, a first circuit 122, and a second circuit 124. The plural first pads 110 are disposed along one side of the semiconductor chip 100, forming a first pad row. The plural second pads 112 are disposed on a side of the plural first pads 110, adjacent to the center of the semiconductor chip 100, forming a second pad row. The first circuit 122 is connected to the plural first pads 110. The first circuit 122 is controlled by eight signals applied to the first pads. The second circuit 124 is connected to the plural second pads 112, having a function differing from that of the first circuit 122. The second circuit 124 is controlled by seven signals applied to the second pads. The semiconductor chip 108, the wiring substrate 400, 420 are sealed with resin as a final product.

The wiring substrate 400 has plural first terminals 410. The wiring substrate 400 is, for example, a lead frame. In such a case, the first terminal is an inner lead. The plural first wires 500 each have one end connected to each of the plural first terminals 410, and the other end connected to each of the first pads 110. The plural first wires 500 do not intersect each other. The plural first wires 500 are parallel with each other, and an interval s1 between the first wires 500 adjacent to each other is not less than 40 μm, for example, 90 μm.

With the exemplary embodiment, the semiconductor chip 100 is rectangular or square in shape. Further, the plural first pads 110, and the plural second pads 112 are formed so as to be disposed along two sides 102, 104 of the semiconductor chip 100, opposing each other, respectively. Then, the center of the plural second pads 112 is positioned between the first pads 110 adjacent to each other, as seen in a direction in which the first pad row is extended. In consequence, the plural first pads 110, and the plural second pads 112 are disposed in a staggered arrangement. The first pad 110 is identical in plane shape to the second pad 112.

The semiconductor chip 100 has plural third pads 114, and a common circuit 126 while the wiring substrate 400 has second terminals 420. In the case where the wiring substrate 400 is a lead frame, the second terminal 420 is an inner lead. The plural third pads 114 are disposed along remaining two sides 106, 108 of the semiconductor chip 100, respectively. The plural third pads 114 are connected to plural the second terminals 420, respectively, via each of plural second wires 510. The plural second wires 510 are parallel with each other.

The common circuit 126 is a circuit (for example, a power supply circuit) that is used either in the case where the first wire 500 is connected to the first circuit 122, or in the case where the first wire 500 is connected to the second circuit 124, the common circuit 126 being connected to the plural third pads 114.

The density and angle of the bonding wires 500 connected to the first pad 110 in FIG. 1 are a constant in any place where the bonding wires 500 are provided.

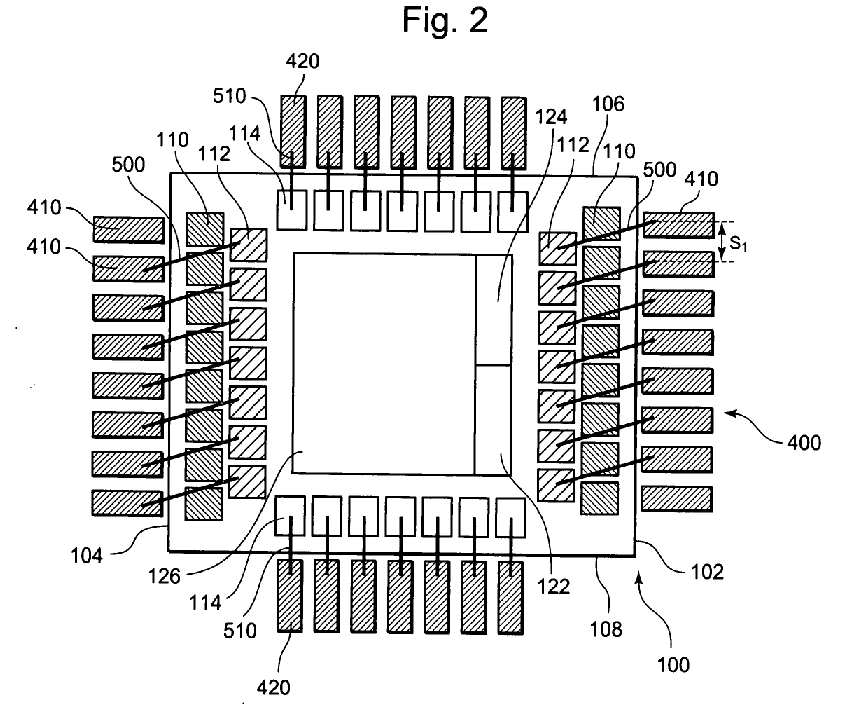

FIG. 2 is a plan view of the semiconductor device shown in FIG. 1, showing an example wherein the other end of the first wire 500 is connected to the second pad 112. The first wires 500 do not intersect each other either. More specifically, the first wires 500 are parallel with each other, and an interval s1 between the first wires 500 adjacent to each other is not less than 40 μm. As compared with the example shown in FIG. 1, the first wire 500 is found longer, and an angle which the first wire 500 forms with the first terminal 410 is found different. The semiconductor chip 108 and the wiring substrate 400, 420 of FIG. 2 are sealed with a resin as a final product. The density and angle of the bonding wires 500 connected to the second pad 112 in FIG. 1 are a constant in any place where the bonding wires 500 are provided. Such a layout as described above can be implemented by altering design rules for a design support system for use in designing of, for example, the semiconductor chip 100.

Now, operational effects of the exemplary embodiment are described hereinafter. First, the plural first wires 500 do not intersect (i.e. neither contact nor overlap) each other regardless of whether the plural first wires 500 are connected to the plural first pads 110 or the plural second pads 112, respectively. For this reason, it is possible to widen the narrowest part of an interval between the first wires 500 adjacent to each other (hereinafter referred to as a critical interval). Furthermore, by changing the length and the angle of the first wire 500, it is possible to switch between connection of the first terminal 410 of the wiring substrate 400 to the first pad 110, and connection of the same to the second pad 112.

If it is provided a semiconductor device which has the semiconductor chip 100 and the first terminals 410 without having bonding wires 500 for connecting the first terminals 410 with the first pads 110, then, normally, a portion of the first pads 110 adjacent to the first function circuit 122 and a portion of the second pads 112 adjacent to the first function circuit 122 are assigned for the first function circuit 122 in order to connect the first function circuit 122 with any necessary pads. In this case, the bonding wires 500 are connected to the first pads 110 as well as the second pads 112 arranged at a portion adjacent to the first function circuit 12. On the other hand, the bonding wires 500 are connected to the first terminals arranged in parallel with a constant pitch. Therefore, the density and angle of the wires 500 are not a constant at a place where the wires 500 are provided. Accordingly, this connection method has a problem to reduce its process yield.

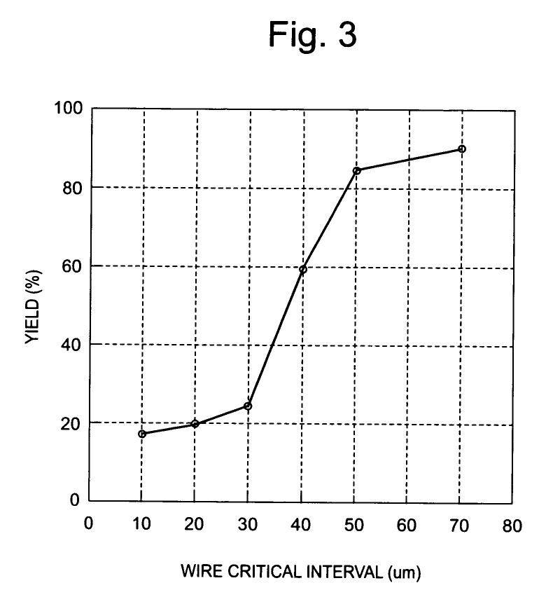

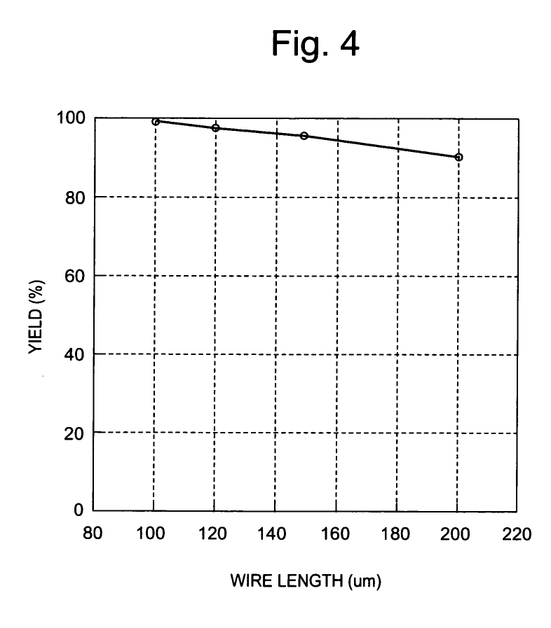

FIG. 3 is a view showing a relation between a wire critical interval and a semiconductor device yield, and FIG. 4 is a view showing a relation between a wire length and a semiconductor device yield. As shown in FIG. 3, as the wire critical interval becomes narrower, so the yield abruptly deteriorates. If the wire critical interval is 30 μm or less, in particular, then the semiconductor device yield is found at not more than 30%. In contrast, as shown in FIG. 4, as the length of a wire increases, so the yield gradually deteriorates; however, the yield hardly drops to 80% or less.

Accordingly, as is the case with the exemplary embodiment, if switching on whether the first terminal 410 is connected to the first pad 110 or to the second pad 112 is made by changing the length and the angle of the first wire 500, then it is possible to improve the semiconductor device yield as compared with the case where the first wires 500 intersect each other, and the wire critical interval becomes smaller. This effect will become more pronounced if the interval between the first wires 500 adjacent to each other, that is, the critical interval is 40 μm or more, particularly 50 μm or more. Moreover, the bonding wires 500 of the exemplary embodiment are arranged substantially in parallel or in a same pitch. Therefore, it is not to need considering the effect shown in FIG. 3. Designer can focus on the effect shown in FIG. 4.

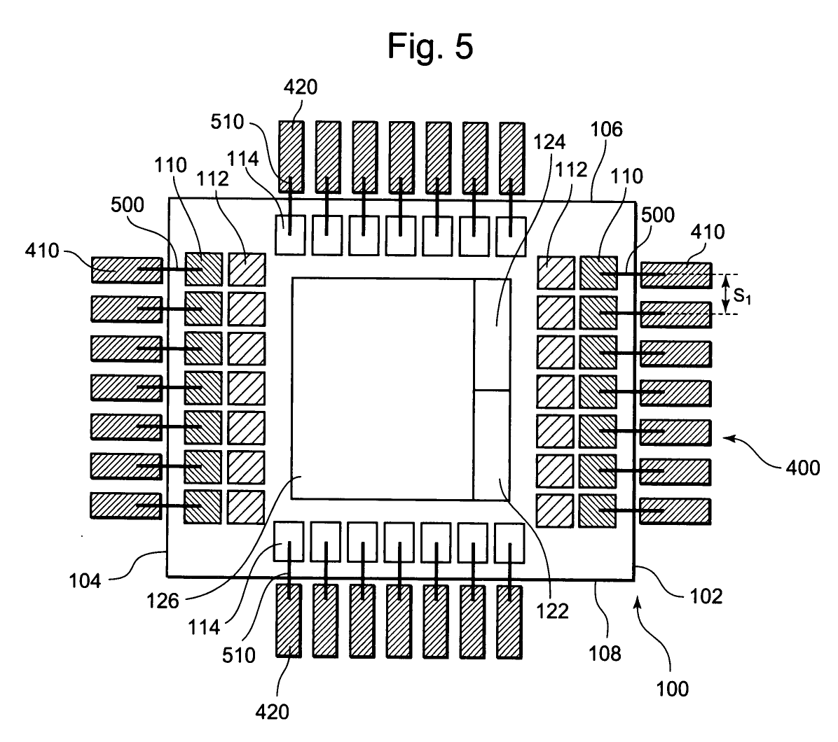

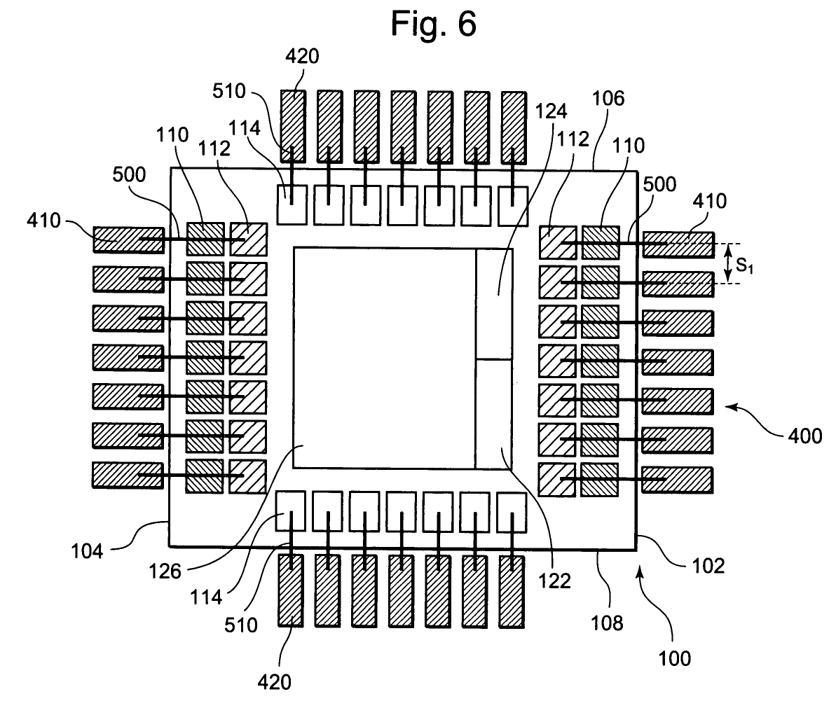

FIGS. 5 and 6 each are a plan view showing a configuration of a second exemplary embodiment of a semiconductor device according to the invention. This semiconductor device is substantially identical to the semiconductor device according to the first exemplary embodiment except that plural first pads 110, and plural second pads 112, on a semiconductor chip 100, together with plural first terminals 410 of a wiring substrate 400, are disposed at positions identical to each other as seen in a direction in which sides 102, 104 are extended.

FIG. 5 shows a state where a first wire 500 connects the first terminal 410 to the first pad 110, and FIG. 6 shows a state where the first wire 500 connects the first terminal 410 to the second pad 112. In either of the figures, the plural first wires 500 are parallel with each other, and an interval s1 between the first wires 500 adjacent to each other is not less than 40 μm. The first function circuit 112 and the second function circuit 124 have a different function, but use the same number of pads. That is, the first function circuit 110 is connected to seven first pads 110 through internal wires (not shown). The second function circuit 112 is connected to seven second pads 112 through internal wires (not shown).

The density and angle of the bonding wires 500 connected to the first pad 110, the second pad 112 are a constant in any place where the bonding wires 500 are provided, in FIGS. 5 and 6, respectively.

With the exemplary embodiment as well, the same effect as that for the first exemplary embodiment can be obtained. Furthermore, since the plural first pads 110, the plural second pads 112, and the plural first terminals 410 are disposed at positions identical to each other, as seen in the direction in which the sides 102, 104 are extended, it is possible to switch over between the pads electrically continuous with the first terminals 410, respectively, by simply changing the length of the first wire 500 even if the angle of the first wire 500 is not changed.

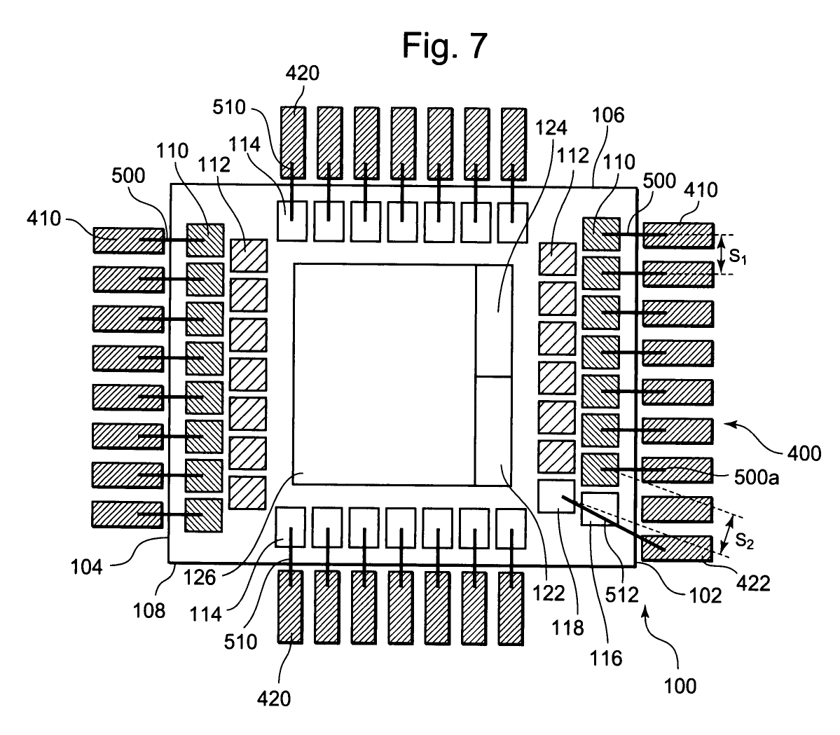

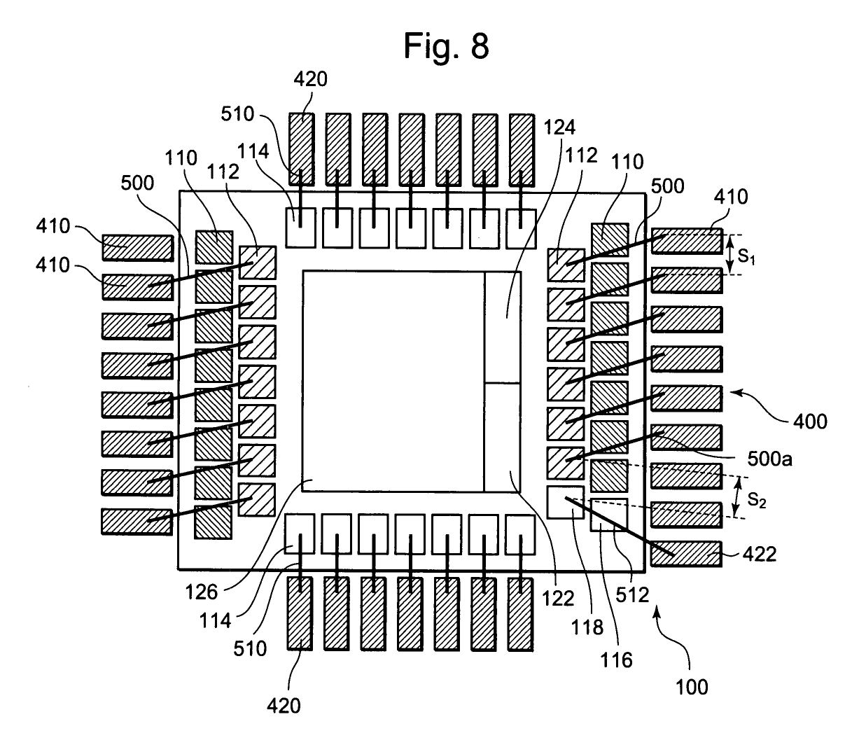

FIGS. 7 and 8 each are a plan view showing a configuration of a third exemplary embodiment of a semiconductor device according to the invention. This semiconductor device is substantially identical in configuration to the semiconductor device according to the first exemplary embodiment except for the following point. The first function circuit is connected to seven first pads 110 and the second function circuit is connected to six second pads 112.

A pad positioned at one end of a first pad row is not the first pad 110 but a dummy pad 116. Further, a pad positioned at one end of a second pad row is not the second pad 112 but a third pad 118. The third pad 118 is continuous with a common circuit 126 as is the case with the third pad 114.

Further, at least one of plural terminals of the wiring substrate 400, disposed along a side 102 of the semiconductor chip 100, is a second terminal 422. With the exemplary embodiment, the second terminal 422 is positioned at an end of a terminal row. The second terminal 422 is connected to the third pad 118 of the second pad row with the use of a wire 512.

FIG. 7 shows a state where the first wire 500 connects the first terminal 410 to the first pad 110, and FIG. 8 shows a state where the first wire 500 connects the first terminal 410 to the second pad 112. In either of the figures, the wire 512 connects the second terminal 422 to the third pad 118 of the second pad row. Further, the plural first wires 500 are parallel with each other, and an interval s1 between the first wires 500 adjacent to each other is not less than 40 μm. An interval s2 between a wire 500a adjacent to the wire 512, and the wire 512 is not less than 40 μm either.

The density and angle of the bonding wires 500 connected to the first pad 110, the second pad 112 are a constant in any place where the bonding wires 500 are provided, in FIGS. 7 and 8, respectively. As shown in FIGS. 7 and 8, though the bonding wire 512 is provided with different angle from the bonding wires 500, the bonding wire 512 is arranged by S2 apart from the adjacent end of the bonding wires 500, so that there is no problem to reduce its process yield.

With the exemplary embodiment as well, the same effect as that for the first exemplary embodiment can be obtained.

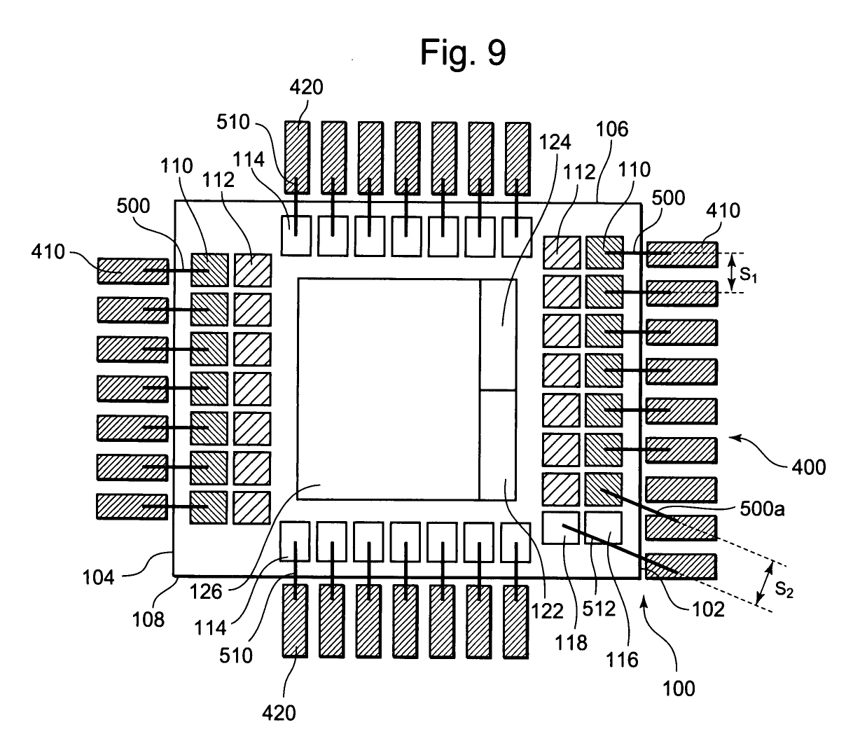

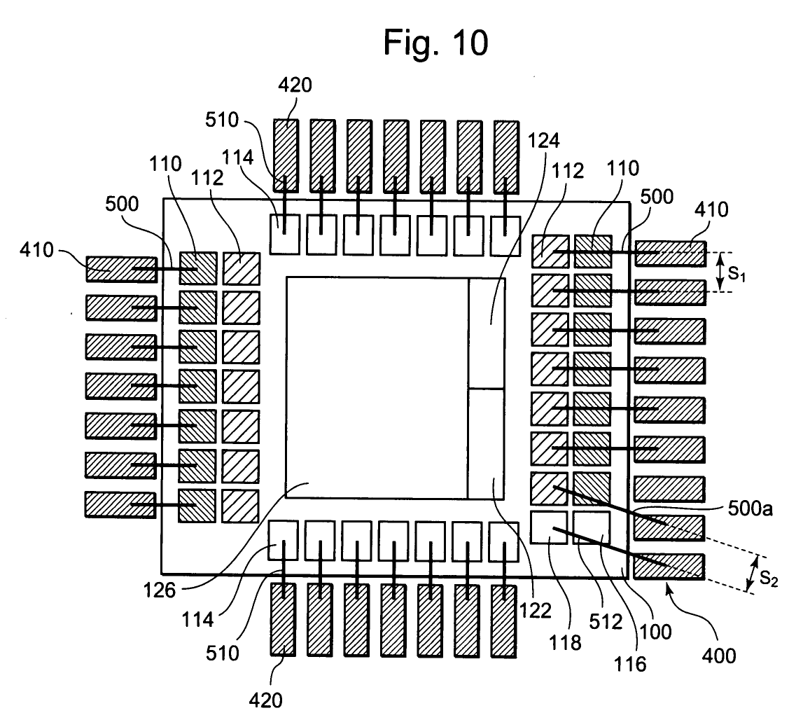

FIGS. 9 and 10 each are a plan view showing a configuration of a fourth exemplary embodiment of a semiconductor device according to the invention. FIG. 9 shows a state where the first wire 500 connects the first terminal 410 to the first pad 110, and FIG. 10 shows a state where the first wire 500 connects the first terminal 410 to the second pad 112. This semiconductor device is identical in configuration to the semiconductor device according to the first exemplary embodiment except for the following point. The first function circuit is connected to seven first pads 110 and the second function circuit is connected to seven second pads 112.

As for a positional relation between the plural first pads 110 and a dummy pad 116, forming a first pad row, and the plural second pads 112 and a third pad 118, forming a second pad row, the exemplary embodiment is identical to the second exemplary embodiment. Further, a wire 500a as one of the first wires 500 is not parallel with the rest of the first wires 500. In the case of respective examples shown in those figures, the wire 500a is positioned so as to be adjacent to a wire 512, however, the position of the wire 500a is not limited thereto. By simply changing the length of each of the first wires 500 other than the wire 500a, switchover between the pads electrically continuous with the first terminal 410 can be implemented.

With the exemplary embodiment as well, the same effect as that for the third exemplary embodiment can be obtained. The bonding wire 500 connected to the far end first pad 110 is arranged at an angle with respect to the other bonding wires 500. However, because the distance between the bonding wire 500 at the far end and the adjacent bonding wire 500 is larger than the distance between the other adjacent bonding wires 500, there is substantially no problem to reduce the process yield.

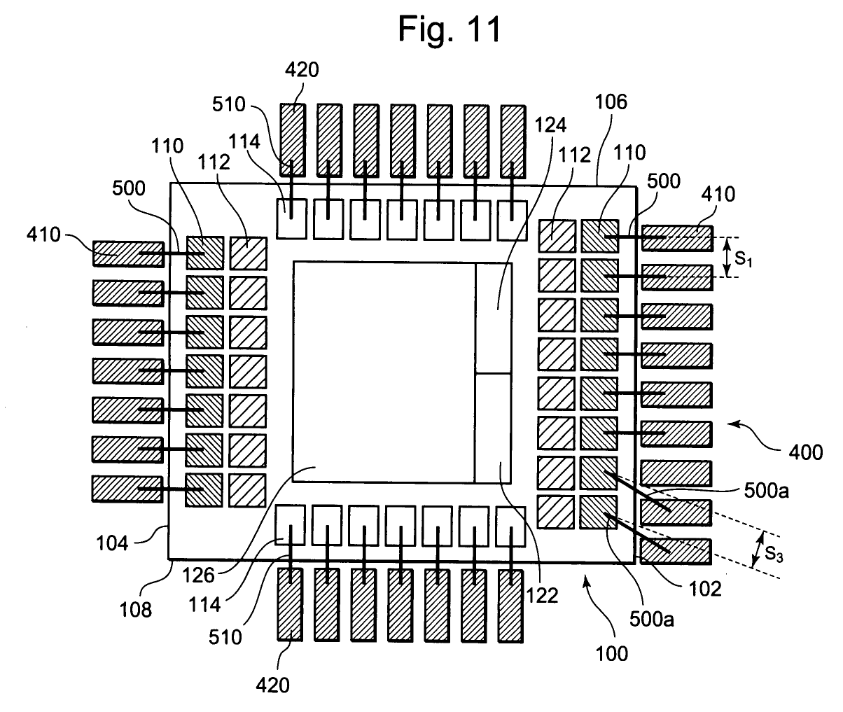

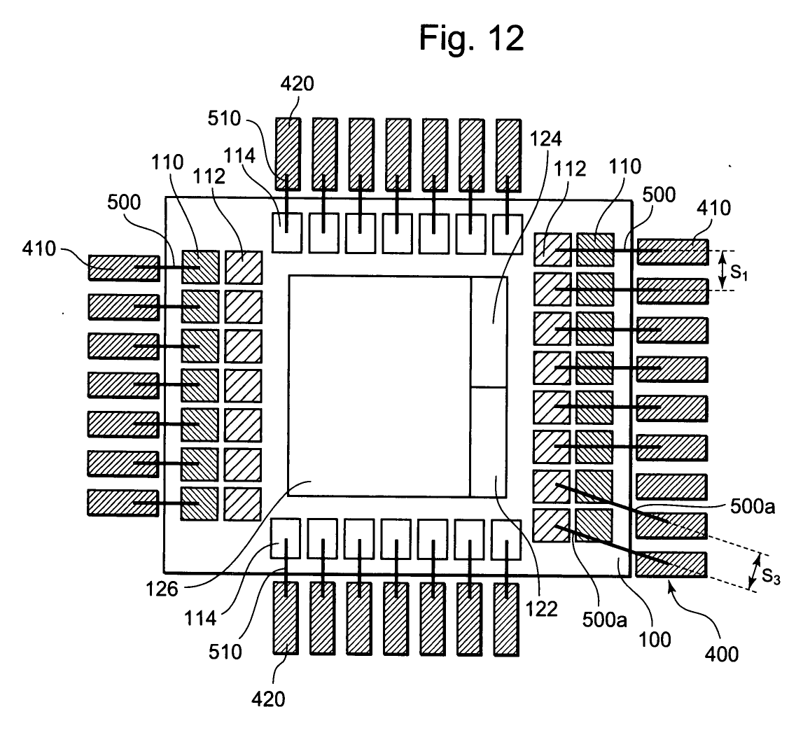

FIGS. 11 and 12 each are a plan view showing a configuration of a fifth exemplary embodiment of a semiconductor device according to the invention. FIG. 11 shows a state where a first wire 500 connects a first terminal 410 to first pad 110, and FIG. 12 shows a state where the first wire 500 connects the first terminal 410 to a second pad 112. This semiconductor device is identical in configuration to the semiconductor device according to the fourth exemplary embodiment except for the following point.

First, a first pad row is made up of first pads 110 only, and a second pad row is made up of second pads 112 only. Accordingly, the semiconductor device according to the exemplary embodiment is not provided with the dummy pad 116, the third pad 118, and the wire 512, as shown in the fourth exemplary embodiment. The first function circuit 122 is connected to eight first pads 110 and the second function circuit 124 is connected to eight second pads 112.

There are provided plural wires 500a that are not parallel with the rest of first wires 500. With respective examples shown in those figures, there are provided two lengths of the wires 500a, each being connected to two pieces of the first pads 110 positioned at an end of the first pad row, or two pieces of the second pads 112. Further, an interval s3 between the wires 500a is not less than 40 μm either. Respective positions of the wires 500a are not limited to those in the respective examples shown in the figures.

With the exemplary embodiment as well, the same effect as that for the fourth exemplary embodiment can be obtained. The bonding wires 500a are arranged at an angle with respect to the other bonding wires 500. However, because the distance between the bonding wires 500 and the adjacent bonding wire 500 is larger than the distance between the other adjacent bonding wires 500, there is substantially no problem to reduce the process yield.

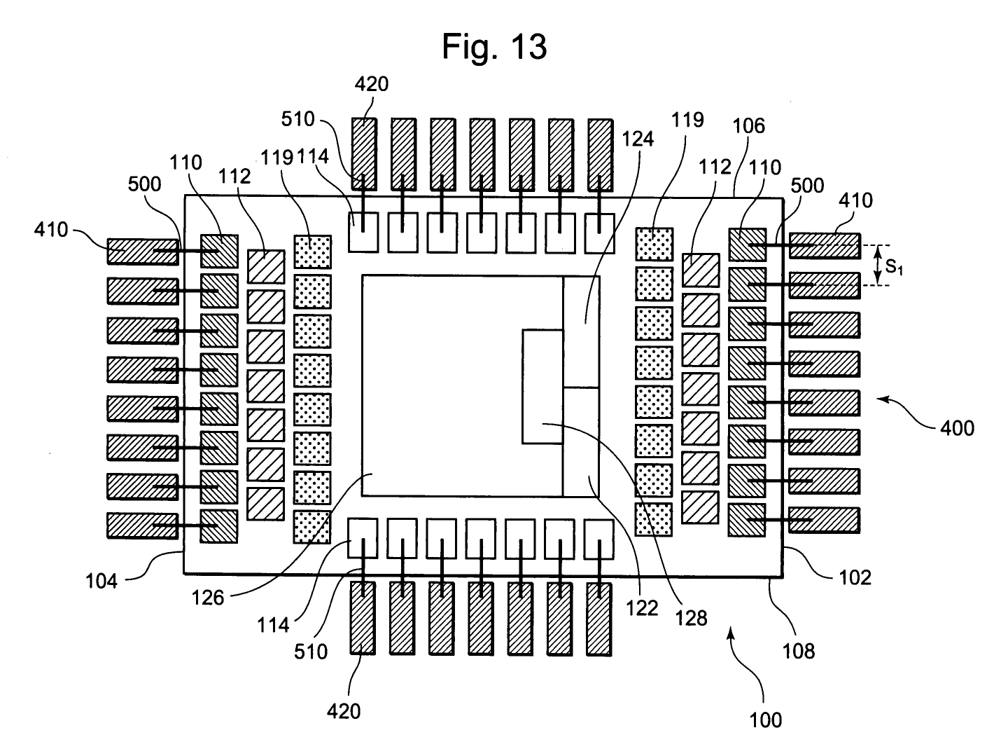

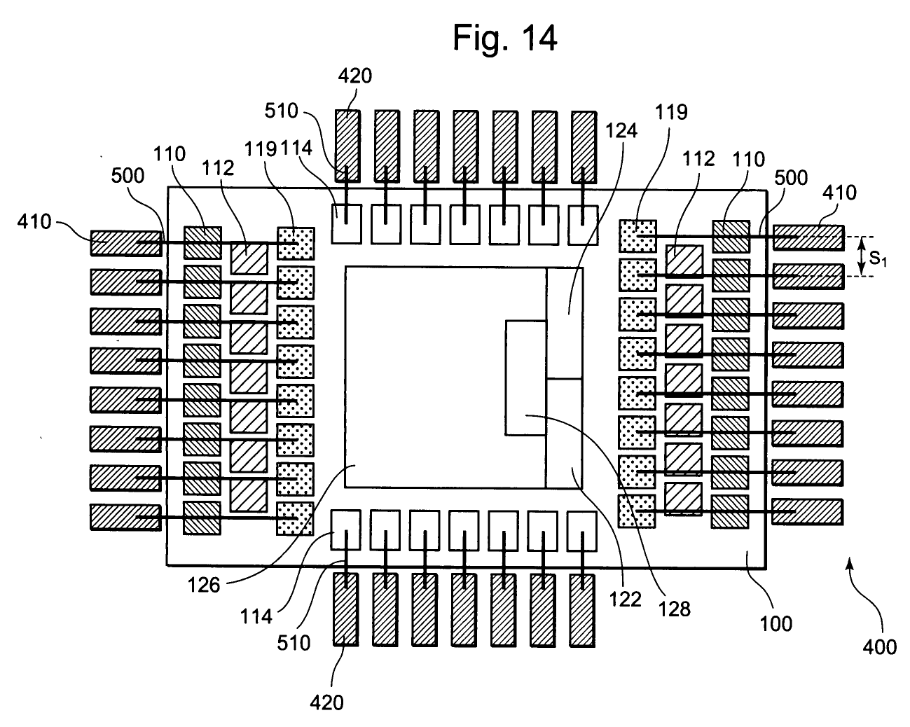

FIGS. 13 and 14 each are a plan view showing a configuration of a sixth exemplary embodiment of a semiconductor device according to the invention. This semiconductor device is identical in configuration to the semiconductor device according to the first exemplary embodiment except for the following point. The first function circuit 112 is connected to eight first pads 110, and the second function circuit is connected to seven second pads 112.

The semiconductor device has a third circuit 128, and plural fourth pads 119. The third circuit 128 has a function differing from that of a first circuit 122, and that of a second circuit 124, and is electrically connected to the plural fourth pads 119. The plural fourth pads 119 are disposed on a side of a second pad row made up of plural second pads 112, adjacent to the center of a semiconductor chip 100, thereby forming a third pad row parallel with sides 102, 104, respectively.

With respective examples shown in those figures, the number of the fourth pads 119 is identical to the number of first pads 110. However, there is no limitation thereto. Further, the plural fourth pads 119 are disposed at positions identical to those of plural first terminals 410, as seen in a direction in which the sides 102 and 104 are extended, however, there is no limitation thereto either.

With the exemplary embodiment, FIG. 13 shows a state where the first wire 500 connects the first terminal 410 to the first pad 110, and FIG. 14 shows a state where the first wire 500 connects the first terminal 410 to the fourth pad 119. In either of the figures, the plural first wires 500 are parallel with each other, and an interval s1 between the first wires 500 adjacent to each other is not less than 40 μm.

With the exemplary embodiment as well, the same effect as that for the first exemplary embodiment can be obtained.

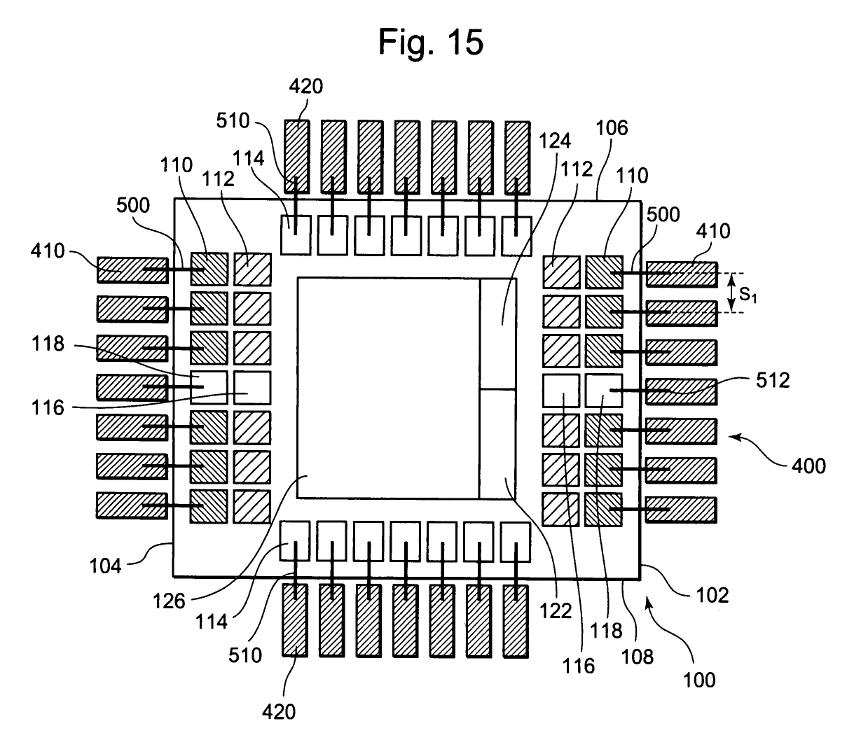

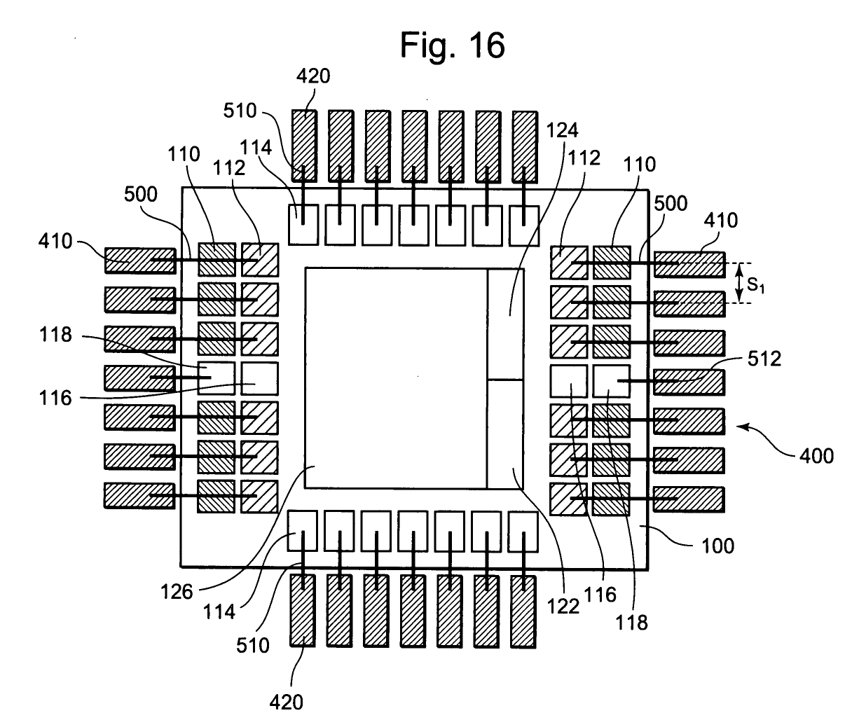

FIGS. 15 and 16 each are a plan view showing a configuration of a seventh exemplary embodiment of a semiconductor device according to the invention. FIG. 15 shows a state where a first wire 500 connects a first terminal 410 to a first pad 110, and FIG. 16 shows a state where the first wire 500 connects the first terminal 410 to a second pad 112. This semiconductor device is identical in configuration to the semiconductor device according to the second exemplary embodiment except for the following point. The first function circuit 122 is connected to six first pads 110, and the second function circuit 124 is connected to six second pads 110.

First, a third pad 118 is included in pads forming a first pad row. As is the case with third pads 114, the third pad 118 is electrically continuous with a common circuit 126. For example, the third pad 118 is applied to a power source. The third pad 118 is at a position other than the respective ends of the first pad row. With respective examples, shown in those figures, the third pad 118 is positioned at the center of the first pad row, however, there is no limitation thereto.

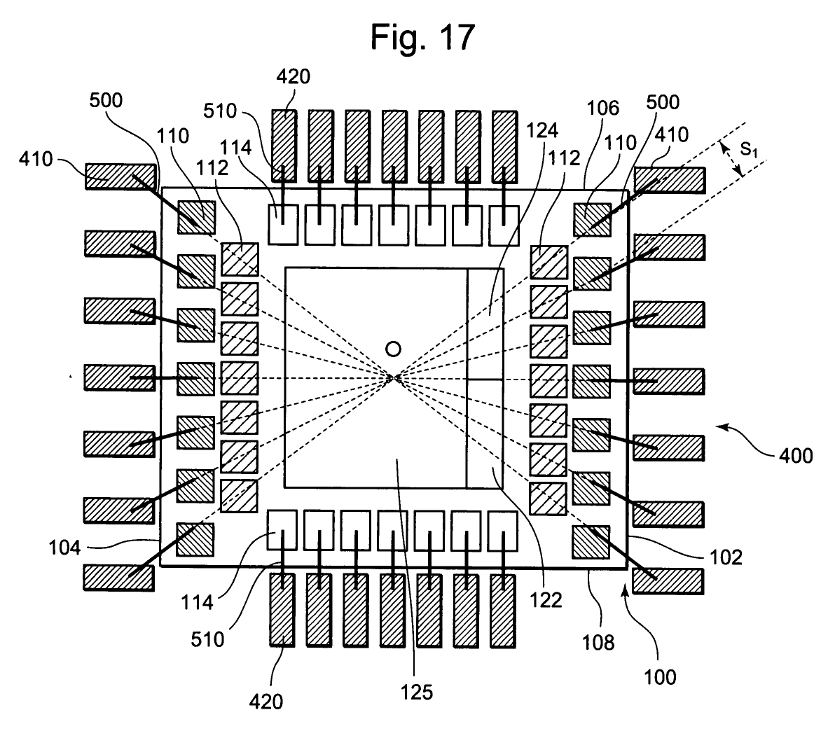

A dummy pad 116 is included in pads forming a second pad row. The dummy pad 116 is disposed at a position other than the respective ends of the second pad row. With respective examples, shown in those figures, the dummy pad 116 is disposed at a position identical to that of the third pad 118, as seen in a direction in which a side 102 is extended, that is, the dummy pad 116 is positioned at the center of the second pad row. However, there is no limitation thereto. Since the third pad 118 is used by the common circuit 126, it is not necessary to switch its position with the dummy pad 116 in FIGS. 16 and 17. Therefore, the bonding wire 512 is placed the same position in FIGS. 15 and 16.

With the exemplary embodiment as well, the same effect as that for the second exemplary embodiment can be obtained. The density and angle of the bonding wires 500 is a constant at the area where the bonding wires 500 are provided, as shown in FIG. 15 and 16.

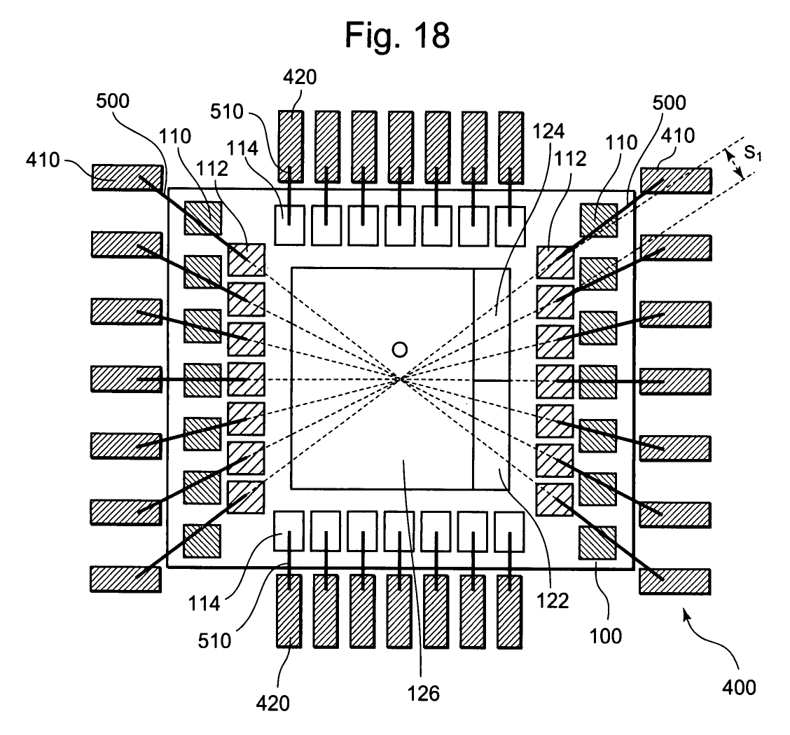

FIGS. 17 and 18 each are a plan view showing a configuration of an eighth exemplary embodiment of a semiconductor device according to the invention. FIG. 17 shows a state where a first wire 500 connects a first terminal 410 to a first pad 110, and FIG. 18 shows a state where the first wire 500 connects the first terminal 410 to a second pad 112. The first function circuit 122 is connected to seven first pads 110, and the second function circuit 124 is connected to seven second pads 112.

This semiconductor device is identical in configuration to the semiconductor device according to the first exemplary embodiment except that the first terminals 410 of a wiring substrate 400, the first pads 110 of a semiconductor chip 100, and the second pads 112 of the semiconductor chip 100 are radially disposed with respect to the center O of the semiconductor chip 100.

More specifically, the first terminal 410, the first pad 110, and the second pad 112, corresponding to each other, are all disposed on the same straight line. The straight line passes through the center O of the semiconductor chip 100. Further, the first wires 500 each are provided along the straight line. In either the state shown in FIG. 17 or the state shown in FIG. 18, the minimum value of an interval s1 between the first wires 500 adjacent to each other is not less than 40 μm.

With the exemplary embodiment as well, the first wires 500 do not intersect each other, so that it is possible to widen the critical interval as compared with the case where the plural first wires 500 intersect (overlap) each other.

Having described the exemplary embodiments of the present invention with reference to the accompanying drawings, as above, it is to be pointed out that those exemplary embodiments are illustrative, and various configurations other than those described in the foregoing can be adopted.

Further, it is noted that Applicant's intent is to encompass equivalents of all claim elements, even if amended later during prosecution.

What is claimed is:

1. A semiconductor device, comprising:
a semiconductor chip including;
a first circuit:
a second circuit having a function differing from that of the first circuit;
a plurality of first pads disposed in a row along one side of the semiconductor chip and connected to the first circuit; and
a plurality of second pads disposed between both of the first and second circuits and the first pads, and connected to the second circuit;
a wiring substrate including a plurality of terminals provided outside of the semiconductor chip; and
a plurality of wires connected between the plurality of terminals and ones of the first pads and the second pads, the wires being free from the other of the first pads and the second pads, and the plurality of wires being not overlapped with each other.

2. The semiconductor device according to claim 1, further comprising:
a third circuit having a function different from the functions of the first and second circuits;
a third pad connected to the third circuit, the third pad being arranged at a position on a line extending in a direction where the first pads are arranged, or on a line extending in a direction where the second pads are arranged; and
a second terminal connected to the third circuit via the third pad.

3. The semiconductor device according to claim 1, wherein the plurality of the wires has an interval not less than 40 μm between first and second wires adjacent to each other.

4. The semiconductor device, as claimed in claim 1,
wherein the semiconductor chip, the wiring substrate and the plurality of wires are resin sealed.

5. The semiconductor device, as claimed in claim 1,
wherein the plurality of wires are arranged in parallel to each other.

6. The semiconductor device, as claimed in claim 1,
wherein the plurality of wires are radially arranged from a center of the semiconductor chip.

7. The semiconductor device, as claimed in claim 2, further comprising:
a dummy pad arranged at a line extending on the third pad and the second terminal, and at a line extending in a direction where the first pads are arranged or the second pads are arranged.

8. The semiconductor device, as claimed in claim 1,
wherein a number of the first pads is different from a number of the second pads so that the first pads and the second pads are arranged in zigzag alignment.

9. The semiconductor device, as claimed in claim 8,
wherein the terminals are arranged so that each of the terminals elongates in a first direction, and each of the wires is arranged in a second direction different from the first direction.

10. The semiconductor device, as claimed in claim 1,
wherein a first group of the wires are arranged in parallel to each other; and
wherein a second group of the wires are arranged in parallel to each other, and at an angle with the first group of the wires.

11. A semiconductor device, comprising:
a semiconductor chip including a first function circuit, a second function circuit, a first pad row arranged along an edge of the semiconductor chip and connected to the first function circuit, a second pad row arranged between both first and second function circuits and the first pad row and connected to the second function circuit, the second pad row being arranged in parallel with the first pad row;
a plurality of inner leads;
a plurality of bonding wires connected between the plurality of inner leads and one of the first and second pad rows, the remaining of the first and second pad rows being free from the inner leads; and
a resin sealing the semiconductor chip, bonding wires and a portion of the inner leads.

12. The semiconductor device, as claimed in claim 11,
wherein the plurality of bonding wires are arranged in parallel to each other.

13. The semiconductor device, as claimed in claim 11,
wherein the plurality of bonding wires are radially arranged from a center of the semiconductor chip.

14. The semiconductor device as claimed in claim 11, further comprising:
a power supply circuit;
a third pad connected to the power supply circuit and arranged on an extended line from one of the first and second pad rows; and
a dummy pad arranged on an extended line from the other of the first and second pad rows, free from the first and second function circuits, the inner leads and the power supply circuit,
wherein a bonding wire is connected to the third pad and an inner lead.

15. The semiconductor device as claimed in claim 14,
wherein the plurality of bonding wires are overlapped.
